(19) United States
(12) Patent Application Publication
(10) Pub. No.: US 2013/0270106 A1
(43) Pub. Date: Oct. 17, 2013

(54) Production of Nanoparticles

(71) Applicant: Lars Allers, Thame (GB)

(72) Inventor: Lars Allers, Thame (GB)

(73) Assignee: MANTIS DEPOSITION LIMITED, Thame, Oxfordshire (UK)

(21) Appl. No.: 13/808,468

(22) PCT Filed: Jul. 8, 2011
(86) PCT No.: PCT/GB11/51280

§ 371 Date: Jan. 31, 2013

(30) Foreign Application Priority Data
Jul. 9, 2010 (GB) 1011628.3

(51) Int. Cl. C23C 14/35

(52) U.S. Cl. CPC C23C 14/352
USPC 204/298.07; 204/298.16

(57) ABSTRACT

A production method for nanoparticles is disclosed which allows excellent control of the production parameters and elevated production rates. It comprises a plurality of sputter targets arranged in a coplanar manner, a first gas supply located between the plurality of sputter targets, for emitting a stream of gas; and a plurality of magnetrons, one located behind each of the sputter targets. Each magnetron can have an independently controlled power supply, allowing close control. For example, the targets could be of different materials allowing variation of the alloying compositions. A plurality of further gas supplies can be provided, each further gas supply providing a supply of gas over a sputter target. The sputter targets can be arranged in a rotationally symmetric manner, ideally symmetrically around the first gas supply. It is particularly convenient for the sputter targets to be located at a surface of a support, within a recessed portion on that surface bounded by an upstand, as this allows the plurality of further gas supplies to be located on the upstand, each directed towards a sputter target. This then permits close control of the gas flow rate and direction over each sputter target.

### FIELD OF THE INVENTION

The present invention relates to an apparatus for producing nanoparticles.

### BACKGROUND ART

There are several methods for creating nanoparticles.

Attrition-based production routes require a ball mill to grind macro or micro scale particles. The resulting particles can be air classified to recover nanoparticles.

Pyrolysis can be employed, by which a vaporous precursor is forced through an orifice at high pressure and burned. The resulting solid (essentially, soot) is air classified to recover oxide particles from by-product gases.

A thermal plasma can be used to evaporate small micrometer size particles from a bulk solid. Nanoparticles are formed when the particles leave the plasma region and cool.

Inert-gas condensation is frequently especially suited to making nanoparticles from metals with low melting points. The metal is vaporized in a vacuum chamber and then supercooled with an inert gas stream. The supercooled metal vapour condenses into nanometer-sized particles, which can be entrained in the inert gas stream and deposited on a substrate or studied in situ.

### SUMMARY OF THE INVENTION

The properties and characteristics of the nanoparticles are dependent on the production route chosen. We have ascertained a production method which allows excellent control of the production parameters and which also allows elevated production rates, in comparison with existing methods.

The present invention therefore provides an apparatus for producing nanoparticles, comprising a plurality of sputter targets arranged in a coplanar manner, a first gas supply located between the plurality of sputter targets, for emitting a stream of gas; and a plurality of magnetrons, one located behind each of the sputter targets.

Each magnetron can have an independently controlled power supply, allowing close control. For example, the targets could be of different materials allowing variation of the alloying compositions.

We prefer to provide a plurality of further gas supplies, each further gas supply providing a supply of gas over a sputter target. The sputter targets can be arranged in a rotationally symmetric manner, ideally symmetrically around the first gas supply. Each of the gas supplies, including the central, first gas supply and the plurality of further gas supplies, may be individually controllable to provide a particular positive or negative gas flow rate. It is particularly convenient for the sputter targets to be located at a surface of a support, within a recessed portion on that surface bounded by an upstand, as this allows the plurality of further gas supplies to be located on the upstand, each directed towards a sputter target. This then permits close control of the gas flow rate and direction over each sputter target.

The apparatus according to embodiments of the present invention allows nanoparticles to be generated in which the mix and relative concentration of different elements can be closely controlled.

### BRIEF DESCRIPTION OF THE DRAWINGS

An embodiment of the present invention will now be described by way of example, with reference to the accompanying figures in which;

FIG. 1 is a frontal view of the sputter targets;

FIG. 2 is a longitudinal section through the nanoparticle production apparatus including the sputter targets of FIG. 1; and

FIG. 3 shows evidence of nanoparticles comprising two separate elements.

### DETAILED DESCRIPTION OF THE EMBODIMENTS

FIG. 2 shows the apparatus 10 in schematic form. A chamber 12 contains a plurality of magnetron sputtering sources to generate a vapour, mounted on a linearly translatable substrate. The interior of the chamber 12 contains an inert gas at a relatively high pressure of a hundred millitorr or more, say up to 5 torr.

Each magnetron sputter source comprises a sputter target 16a, 16b, behind which is positioned a respective magnetron 14a, 14b. Each magnetron 14a, 14b is connected to a respective independently controlled, high-voltage power supply 22a, 22b. Although the power supplies 22 are illustrated in separate housings, it will be apparent to those skilled in the art that a single power supply may provide the necessary independently controlled voltages to the magnetrons. In the illustrated embodiment, the sputter targets 16a, 16b are located at a surface of a support 17, within a recessed portion on that surface bounded by an upstand.

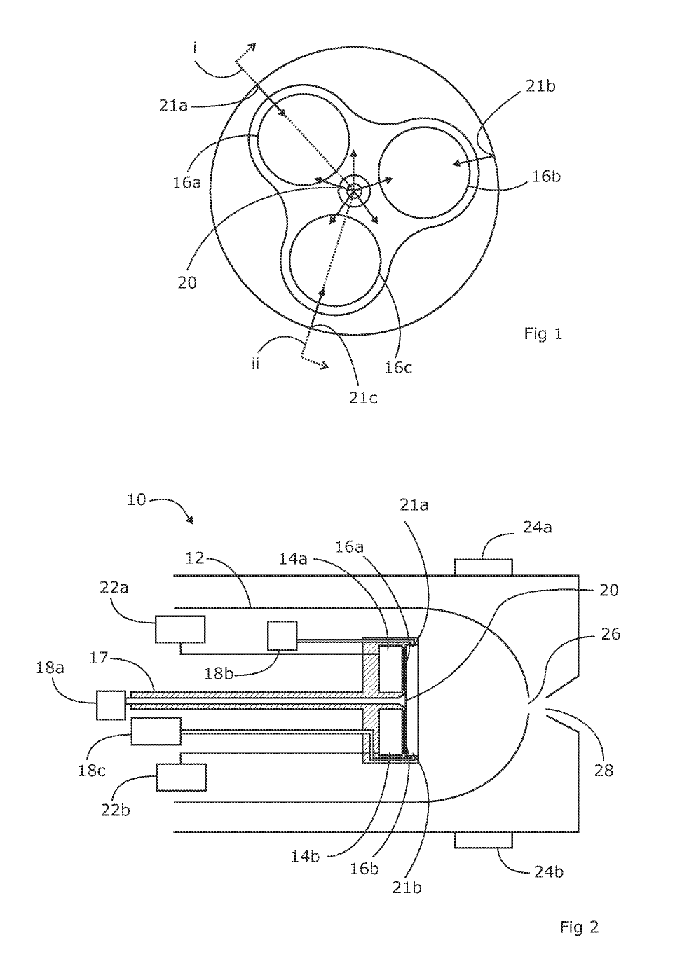

The inert gas is fed into the chamber 12 via a plurality of gas supplies 18a, 18b, 18c, which are coupled to respective outlets in and around the sputter targets 16. For example, a first outlet 20 is positioned in between the plurality of sputter targets, on a central axis of the magnetron sputtering assembly (see FIG. 1). This outlet 20 is coupled to gas supply 18a. Further outlets 21a, 21b are positioned adjacent each respective sputter target 16a, 16b in the upstand, in order to direct the inert gas directly over the target, and these outlets 21a, 21b are coupled to gas supplies 18b and 18c, respectively. The inert gas within the chamber is extracted from an exit aperture 26 directly ahead of the magnetron sputtering assembly. This creates a gas flow through the chamber 12 and establishes a drift of the vapour. During its transit to the exit aperture 26, the vapour condenses to form a nanoparticle cloud.

Electromagnets 24a, 24b on either side of the apparatus may be individually controlled to establish a particular magnetic field within the chamber 12. The magnetic field affects the size and shape of the plasma generated by the magnetrons, and therefore affects the size and rate of production of nanoparticles. For example, a larger plasma effectively decreases the volume in which particles can condense into nanoparticles before exiting the chamber 12, and thus will affect their size.

On exiting the condensation zone defined by the chamber 12, the beam is subject to a large pressure differential and undergoes supersonic expansion. This expanded beam then impinges upon a second aperture 28, which allows the central portion of the beam to pass through, while the background gas and smaller nanoparticles do not pass through. The background gas is then collected by a pumping port (not illustrated) for re-circulation or disposal. This provides a further refinement of the beam as the smaller particles are ‘filtered’ out.

By using magnetron sputtering, a high fraction of the nanoparticles produced are negatively charged. This allows the particles to be accelerated electrostatically across a vacuum to a substrate or object, and thus gain kinetic energy. This can be achieved by raising the substrate or object to a suitably high potential. Non-conductive substrates can be placed behind a conductive mask having an appropriately shaped aperture in the line of sight of the particle beam.

The kinetic energy acquired in flight is lost on impact by way of deformation of the particles. The degree of deformation naturally depends on the energy imparted to the particles in flight. At very high energies, the nanoparticle structure may be lost and the resultant film will be essentially bulk material. At very low energies, the process will be akin to condensation and the film may be insufficiently adherent. Between these extremes, there is scope for deformation of the particles that is mild enough for the surface of the film to retain nanoparticulate properties but for the interface with the substrate to be adherent.

FIG. 2 is a cross-sectional view of the apparatus according to embodiments of the present invention, and therefore only two magnetrons and two sputter targets are shown for clarity. Further embodiments of the present invention may comprise more than two magnetrons and respective sputter targets. FIG. 1 is a frontal view of a sputter target assembly according to an embodiment of the present invention comprising three targets 16a, 16b, 16c.

As can be seen from FIG. 1, and particularly the dotted lines marked i and ii, the targets are arranged in a rotationally symmetric manner about a central axis of the sputtering assembly. A gas outlet 20, located on the central axis, provides a supply of inert gas away from the assembly. Further gas outlets 21a, 21b, 21c are positioned in the upstand outside each respective target 16, and direct inert gas over that particular target towards the central axis. These gas outlets may be connected to separate, independently controlled gas supplies in order to closely control the gas flow over each target. Any or all of the gas supplies may be capable of generating negative gas flows (i.e. sucking gas back into the supply).

Although three targets 16 are shown in FIG. 1, it will again be apparent to those skilled in the art that the assembly according to embodiments of the present invention may comprise any number of targets greater than one.

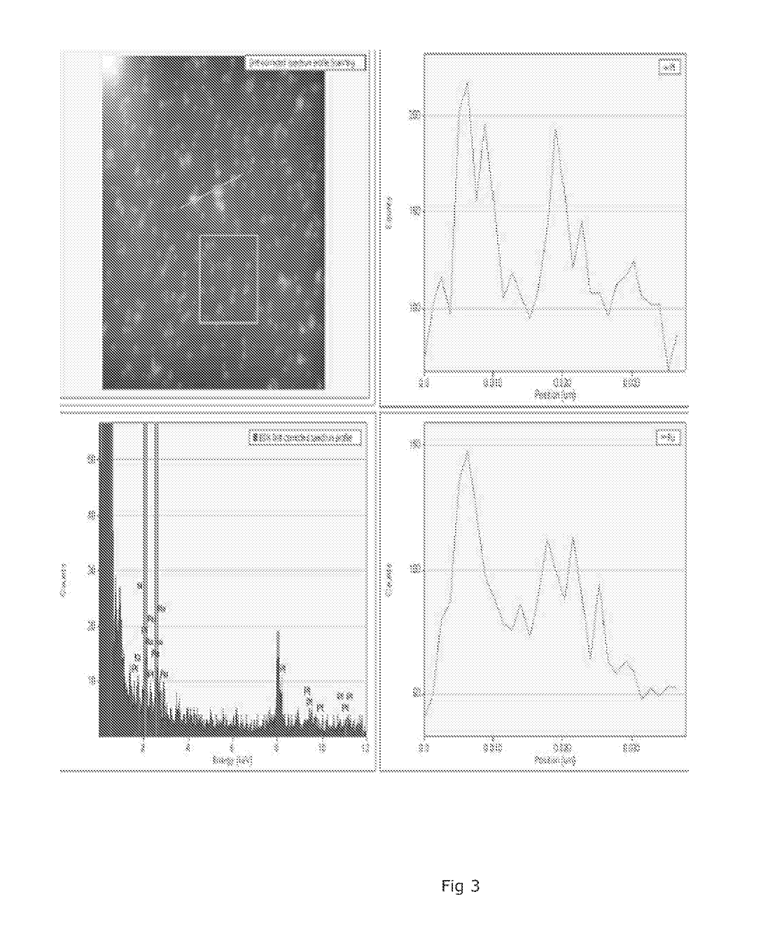

Thus the present invention allows nanoparticles of different elements and compounds to be created, by placing sputtering targets of different materials on each of the magnetrons. For example, platinum-ruthenium (PtRu) nanoparticles can be created using platinum and ruthenium targets, as shown in FIG. 3.

The top-left image is a transmission electron microscopy image of the sample under analysis. The bottom-left image is an energy dispersive X-ray (EDX) spectrum of the area enclosed by the square in the top-left image. Both platinum and ruthenium are evident in the spectrum. The top-right and bottom-right spectra are EDX measurements of platinum and ruthenium content respectively measured along the oblique line in the top left hand side image, which runs across two larger nanoparticles and a third, smaller nanoparticle. There are peaks in both the platinum and ruthenium profiles corresponding to the positions of the three nanoparticles along the line, providing clear evidence that those nanoparticles contain both platinum and ruthenium.

The present invention therefore provides an apparatus for producing nanoparticles with greater control and precision than previously possible. Moreover, it has been shown that nanoparticles with multiple different components can be created.

It will of course be understood that many variations may be made to the above-described embodiment without departing from the scope of the present invention.

1. An apparatus for producing nanoparticles, comprising:
a plurality of sputter targets arranged in a coplanar manner;
a first gas supply located between the plurality of sputter targets, for emitting a stream of gas; and
a plurality of magnetrons, one located behind each of the sputter targets.

2. An apparatus according to claim 1, wherein each magnetron has an independently controlled power supply.

3. An apparatus as claimed in claim 1 further comprising a plurality of further gas supplies, each further gas supply providing a supply of gas over a sputter target.

4. An apparatus as claimed in claim 1 in which the sputter targets are arranged in a rotationally symmetric manner.

5. An apparatus as claimed in claim 4 in which the sputter targets are arranged symmetrically around the first gas supply.

6. An apparatus as claimed in claim 1 in which the sputter targets are located at a surface of a support, within a recessed portion on that surface bounded by an upstand.

7. An apparatus as claimed in claim 6, further comprising a plurality of further gas supplies, each further gas supply providing a supply of gas over a sputter target, in which each further gas supply comprises an outlet located on the upstand and is directed towards a sputter target of the plurality of sputter targets.

8. An apparatus as claimed in claim 1, wherein the plurality of sputter targets comprise a plurality of different sputtering materials.

9. An apparatus for producing nanoparticles substantially as herein described with reference to and/or as illustrated in the accompanying figures.
